(19) United States
(12) Patent Application Publication
(10) Pub. No.: US 2017/0278679 A1
(43) Pub. Date: Sep. 28, 2017

(54) METHOD AND APPARATUS FOR CONTROLLING PROCESS WITHIN WAFER UNIFORMITY

(71) Applicant: Lam Research Corporation, Fremont, CA (US)

(72) Inventors: Ivelin Angelov, San Jose, CA (US); Christian Siladie, Castro Valley, CA (US); Arun Keshavamurthy, Karnataka (IN); Joon Hong Park, Dublin, CA (US); Jason Treadwell, Gilroy, CA (US)

(21) Appl. No.: 15/464,793

(22) Filed: Mar. 21, 2017

Related U.S. Application Data
(60) Provisional application No. 62/312,638, filed on Mar. 24, 2016.

(51) Int. Cl. H01J 37/32; H01L 21/683; H01L 21/67

(52) U.S. Cl. CPC H01J 37/32449; H01J 37/321; H01J 37/32715; H01L 21/67069; H01L 21/6831; H01J 2237/334; H01J 2237/202

(57) ABSTRACT

A substrate processing system includes a gas distribution device arranged to distribute process gases over a surface of a substrate arranged in a substrate processing chamber having an upper chamber region and a lower chamber region. A substrate support is arranged in the lower chamber region of the substrate processing chamber below the gas distribution device. A ring is arranged in the lower chamber region of the substrate processing chamber below the gas distribution device and above the substrate support. The ring is arranged to surround a faceplate of the gas distribution device and a region between the gas distribution device and the substrate support, and a gap is defined between the substrate support and the ring.

### CROSS-REFERENCE TO RELATED APPLICATIONS

This application claims the benefit of U.S. Provisional Application No. 62/312,638, filed on Mar. 24, 2016. The entire disclosure of the application referenced above is incorporated herein by reference.

### FIELD

The present disclosure relates to substrate processing, and more particularly to systems and methods for controlling distribution of process materials.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system may be used to etch film on a substrate such as a semiconductor wafer. The substrate processing system typically includes a processing chamber, a gas distribution device and a substrate support. During processing, the substrate is arranged on the substrate support. Different gas mixtures may be introduced into the processing chamber and radio frequency (RF) plasma may be used to activate chemical reactions.

The gas distribution device (e.g., a showerhead) is arranged above the substrate support with a fixed gap between the gas distribution device and the substrate. The gas distribution device distributes chemical reactants over the surface of the substrate during various process steps.

### SUMMARY

A substrate processing system includes a gas distribution device arranged to distribute process gases over a surface of a substrate arranged in a substrate processing chamber having an upper chamber region and a lower chamber region. A substrate support is arranged in the lower chamber region of the substrate processing chamber below the gas distribution device. A ring is arranged in the lower chamber region of the substrate processing chamber below the gas distribution device and above the substrate support. The ring is arranged to surround a faceplate of the gas distribution device and a region between the gas distribution device and the substrate support, and a gap is defined between the substrate support and the ring.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is an example processing chamber without a flow-controlling feature;

FIG. 2A illustrates example flow distributions in a processing chamber without a flow-controlling feature;

FIG. 2B illustrates example non-uniformity percentages in flow distributions in a processing chamber without a flow-controlling feature;

FIGS. 3A, 3B, and 3C illustrate flow patterns in a processing chamber without a flow-controlling feature;

FIG. 4 is a functional block diagram of an example processing chamber including a flow-controlling feature according to the present disclosure;

FIG. 5 is an example processing chamber including a flow-controlling feature according to the present disclosure;

FIG. 6A illustrates example flow distributions for a first recipe in a processing chamber including a flow-controlling feature according to the present disclosure;

FIG. 6B illustrates example non-uniformity percentages in flow distributions for a first recipe in a processing chamber including a flow-controlling feature according to the present disclosure;

FIG. 7A illustrates example flow distributions for a second recipe in a processing chamber including a flow-controlling feature according to the present disclosure;

FIG. 7B illustrates example non-uniformity percentages in flow distributions for a second recipe in a processing chamber including a flow-controlling feature according to the present disclosure;

FIG. 8A illustrates example flow distributions for a third recipe in a processing chamber including a flow-controlling feature according to the present disclosure;

FIG. 8B illustrates example non-uniformity percentages in flow distributions for a third recipe in a processing chamber including a flow-controlling feature according to the present disclosure;

FIGS. 9A and 9B show an example substrate processing chamber including adjustable annular rings according to the present disclosure; and

FIG. 10 shows steps of an example substrate processing method according to the present disclosure.

In the drawings, reference numbers may be reused to identify similar and/or identical elements.

### DETAILED DESCRIPTION

A gas distribution device (e.g., a showerhead) in a substrate processing system distributes chemical reactants (e.g., gases) over the surface of a substrate. The substrate is arranged on a substrate support below the gas distribution device. Typically, the gas distribution device includes a faceplate having a plurality of openings or holes for distributing the gases provided from above the faceplate. Gas distribution is affected by a variety of factors including, but not limited to, size and density of the openings, flow uniformity above the faceplate, the mixture of process gases being provided, flow of the gases (e.g., flow rates), etc.

Uniform distribution of gases over the substrate significantly affects the accuracy and efficiency of the process step being performed. Accordingly, various features may be implemented to control the distribution of gases to improve processing. In some examples, faceplates may be interchangeable. For example, a faceplate having a desired hole pattern, hole size, etc. may be selected and installed for a particular process. However, changing the faceplate between processes and/or process steps may lead to loss of productivity, extended downtimes, increased maintenance and cleaning, etc.

Systems and methods according to the principles of the present disclosure provide a flow-controlling feature (e.g., an annular ring or other barrier) within a processing chamber below the faceplate and selectively adjust a height of the substrate support to control an effective gap between an upper surface of the substrate and the flow-controlling feature. Although described herein as an annular ring, the flow-controlling feature may have other suitable shapes.

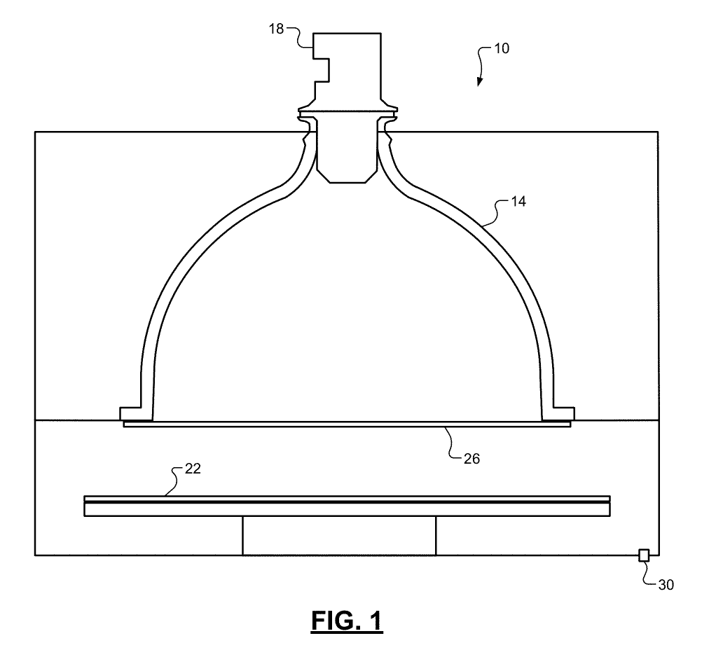

Referring now to FIG. 1, an example substrate processing chamber 10 includes a gas distribution device such as a showerhead 14. The showerhead 14 receives one or more gases via an inlet 18 and distributes the gases into a reaction volume including a substrate (e.g., a wafer) 22. The showerhead 14 distributes the gases through a faceplate 26. The gases may be evacuated from the chamber 10 via an outlet 30. As shown the showerhead 14 does not include a flow-controlling feature according to the principles of the present disclosure.

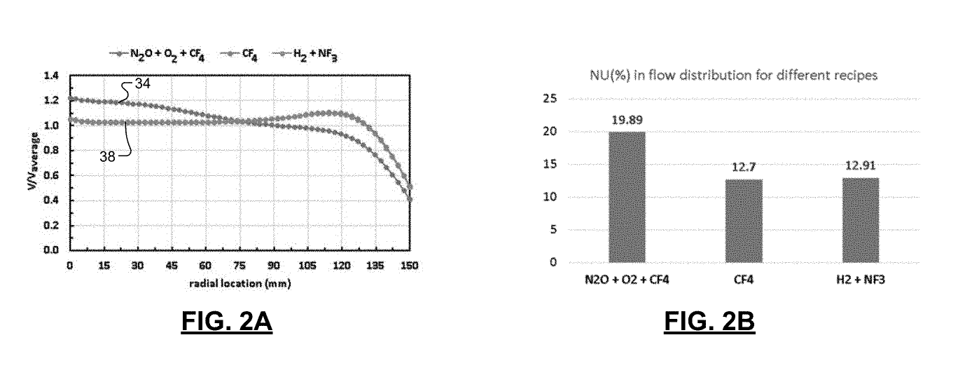

FIG. 2A illustrates different flow distributions (e.g., represented as local velocity normalized by average velocity) of respective recipes supplied in the substrate processing chamber 10 at approximately 0.1 inches above the surface of the substrate 22. Velocity varies as radial distance from a center of the substrate 22 increases (e.g., from 0 to 150 mm). The flow distribution for a recipe corresponding to N₂O+O₂+CF₄ is shown at 34 and the flow distributions for recipes corresponding to CF₄ and H₂+NF₃ are shown at 38. For 34, flow is relatively high at the center and relatively low at the edge of the substrate 22. Conversely, for 38, the flow is relatively uniform in an inner region of the substrate, increases to a peak at approximately 120 mm from the center, and then sharply decreases at the edge of the substrate 22. Accordingly, flow distribution is shown to vary for different process recipes. FIG. 2B illustrates non-uniformity percentages (NU(%)) in flow distribution for respective recipes.

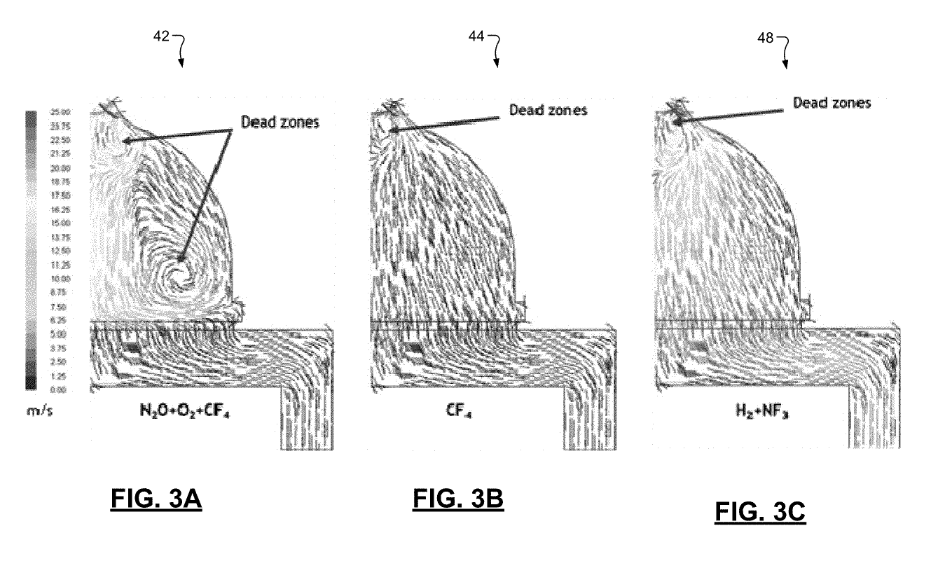

FIGS. 3A, 3B, and 3C illustrate flow patterns for the respective recipes. A flow pattern 42 for N₂O+O₂+CF₄ includes dead zones within the showerhead 14. These dead zones prevent gases from spreading uniformly within the showerhead 14, and therefore interfere with uniform distribution from the faceplate 26. Conversely, flow patterns 44 and 48 for CF₄ and H₂+NF₃, respectively only include relatively small dead zones below the inlet 18. Accordingly, the flow patterns 44 and 48 are relatively uniform within the showerhead 14.

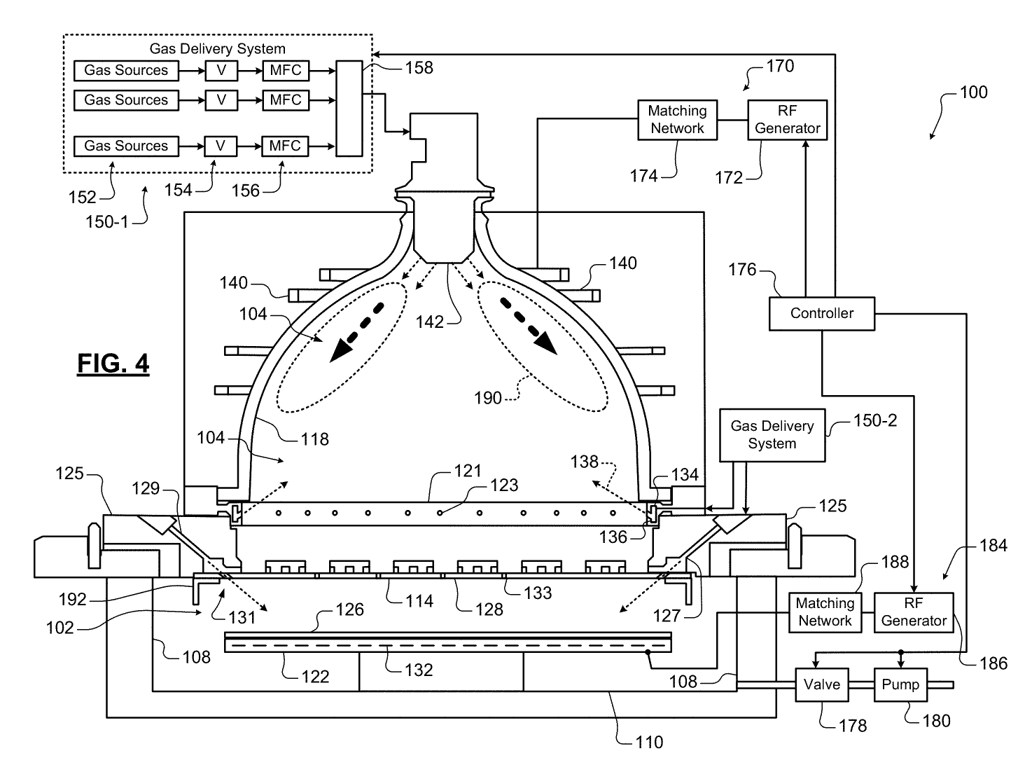

Referring now to FIG. 4, an example of a substrate processing chamber 100 for etching a layer (for example only, a tungsten, or W, layer) of a substrate according to the present disclosure is shown. While a specific substrate processing chamber is shown and described, the methods described herein may be implemented on other types of substrate processing systems.

The substrate processing chamber 100 includes a lower chamber region 102 and an upper chamber region 104. The lower chamber region 102 is defined by chamber sidewall surfaces 108, a chamber bottom surface 110 and a lower surface of a gas distribution device 114.

The upper chamber region 104 is defined by an upper surface of the gas distribution device 114 and an inner surface of a dome 118. In some examples, the dome 118 rests on a first annular support 121. In some examples, the first annular support 121 includes one or more spaced holes 123 for delivering process gas to the upper chamber region 104, as will be described further below. In some examples, the process gas is delivered by the one or more spaced holes 123 in an upward direction at an acute angle relative to a plane including the gas distribution device 114, although other angles/directions may be used. In some examples, a gas flow channel 134 in the first annular support 121 supplies gas to the one or more spaced holes 123.

The first annular support 121 may rest on a second annular support 125 that defines one or more spaced holes 127 for delivering process gas from a gas flow channel 129 to the lower chamber region 102. In some examples, holes 131 in the gas distribution device 114 align with the holes 127. In other examples, the gas distribution device 114 has a smaller diameter and the holes 131 are not needed. In some examples, the process gas is delivered by the one or more spaced holes 127 in a downward direction towards the substrate at an acute angle relative to the plane including the gas distribution device 114, although other angles/directions may be used.

In other examples, the upper chamber region 104 is cylindrical with a flat top surface and one or more flat inductive coils may be used. In still other examples, a single chamber may be used with a spacer located between a showerhead and the substrate support.

A substrate support 122 is arranged in the lower chamber region 104. In some examples, the substrate support 122 includes an electrostatic chuck (ESC), although other types of substrate supports can be used. A substrate 126 is arranged on an upper surface of the substrate support 122 during etching. In some examples, a temperature of the substrate 126 may be controlled by a heater plate 132, an optional cooling plate with fluid channels and one or more sensors (not shown), and/or any other suitable substrate support temperature control systems and methods.

In some examples, the gas distribution device 114 includes a showerhead (for example, a plate 128 having a plurality of spaced holes 133). The plurality of spaced holes 133 extend from the upper surface of the plate 128 to the lower surface of the plate 128. In some examples, the spaced holes 133 have a diameter in a range from 0.4″ to 0.75″ and the showerhead is made of a conducting material such as aluminum or a non-conductive material such as ceramic with an embedded electrode made of a conducting material.

One or more inductive coils 140 are arranged around an outer portion of the dome 118. When energized, the one or more inductive coils 140 create an electromagnetic field inside of the dome 118. In some examples, an upper coil and a lower coil are used. A gas injector 142 injects one or more gas mixtures from a gas delivery system 150-1.

In some examples, a gas delivery system 150-1 includes one or more gas sources 152, one or more valves 154, one or more mass flow controllers (MFCs) 156, and a mixing manifold 158, although other types of gas delivery systems may be used. A gas splitter (not shown) may be used to vary flow rates of a gas mixture. Another gas delivery system 150-2 may be used to supply an etch gas or an etch gas mixture to the gas flow channels 129 and/or 134 (in addition to or instead of etch gas from the gas injector 142).

Suitable gas delivery systems are shown and described in commonly assigned U.S. patent application Ser. No. 14/945,680, entitled “Gas Delivery System” and filed on Dec. 4, 2015, which is hereby incorporated by reference in its entirety. Suitable single or dual gas injectors and other gas injection locations are shown and described in commonly assigned U.S. Provisional Patent Application Ser. No. 62/275,837, entitled “Substrate Processing System with Multiple Injection Points and Dual Injector” and filed on Jan. 7, 2016, which is hereby incorporated by reference in its entirety.

In some examples, the gas injector 142 includes a center injection location that directs gas in a downward direction and one or more side injection locations that inject gas at an angle with respect to the downward direction. In some examples, the gas delivery system 150-1 delivers a first portion of the gas mixture at a first flow rate to the center injection location and a second portion of the gas mixture at a second flow rate to the side injection location(s) of the gas injector 142. In other examples, different gas mixtures are delivered by the gas injector 142. In some examples, the gas delivery system 150-1 delivers tuning gas to the gas flow channels 129 and 134 and/or to other locations in the processing chamber as will be described below.

A plasma generator 170 may be used to generate RF power that is output to the one or more inductive coils 140. Plasma 190 is generated in the upper chamber region 104. In some examples, the plasma generator 170 includes an RF generator 172 and a matching network 174. The matching network 174 matches an impedance of the RF generator 172 to the impedance of the one or more inductive coils 140. In some examples, the gas distribution device 114 is connected to a reference potential such as ground. A valve 178 and a pump 180 may be used to control pressure inside of the lower and upper chamber regions 102, 104 and to evacuate reactants.

A controller 176 communicates with the gas delivery systems 150-1 and 150-2, the valve 178, the pump 180, and/or the plasma generator 170 to control flow of process gas, purge gas, RF plasma and chamber pressure. In some examples, plasma is sustained inside the dome 118 by the one or more inductive coils 140. One or more gas mixtures are introduced from a top portion of the chamber using the gas injector 142 (and/or holes 123) and plasma is confined within the dome 118 using the gas distribution device 114.

Confining the plasma in the dome 118 allows volume recombination of plasma species and effusing desired etchant species through the gas distribution device 114. In some examples, there is no RF bias applied to the substrate 126. As a result, there is no active sheath on the substrate 126 and ions are not hitting the substrate with any finite energy. Some amount of ions will diffuse out of the plasma region through the gas distribution device 114. However, the amount of plasma that diffuses is an order of magnitude lower than the plasma located inside the dome 118. Most of ions in the plasma are lost by volume recombination at high pressures. Surface recombination loss at the upper surface of the gas distribution device 114 also lowers ion density below the gas distribution device 114.

In other examples, an RF bias generator 184 is provided and includes an RF generator 186 and a matching network 188. The RF bias can be used to create plasma between the gas distribution device 114 and the substrate support or to create a self-bias on the substrate 126 to attract ions. The controller 176 may be used to control the RF bias.

The substrate processing chamber 100 according to the principles of the present disclosure includes a flow-controlling feature such as an annular ring 192. Characteristics of the ring 192 (e.g., diameter, height, etc.) and a distance of the substrate 126 from the gas distribution device 114 may be adjusted to control flow distribution for various recipes. In one example, a particular ring 192 may be selected and installed for a desired recipe. In other examples, a diameter and/or height of the ring 192 may be adjusted as described below in more detail. Further, the substrate support 122 may be configured to be selectively raised and lowered.

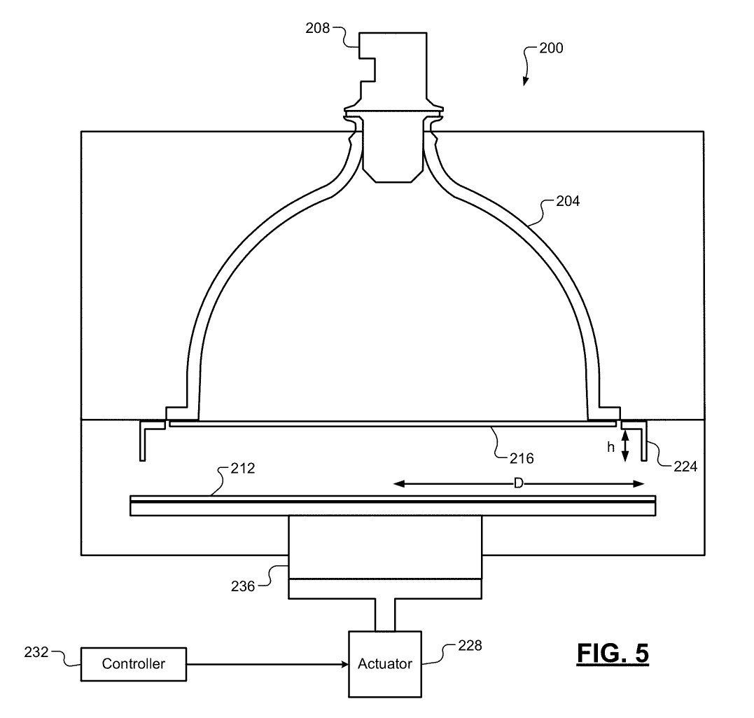

Referring now to FIG. 5, an example substrate processing chamber 200 according to the principles of the present disclosure includes a gas distribution device such as a showerhead 204. The showerhead 204 receives one or more gases via an inlet 208 and distributes the gases into a reaction volume including a substrate (e.g., a wafer) 212. The showerhead 204 distributes the gases through a faceplate 216. The gases may be evacuated from the chamber 200 via an outlet 220. The chamber 200 includes an annular ring 224 having a height h (corresponding to distance from faceplate 216 to a bottom edge of the ring 224) and a distance D (corresponding to a radial distance from a center of the substrate 212 and the ring 224. In some examples, an actuator 228 responsive to a controller 232 may be used to selectively raise and lower a substrate support 236. In this manner, a height of the substrate support 236 may be adjusted to control an effective gap between an upper surface of the substrate 212 and the ring 224. For example, the effective gap may be varied according to a parameters such as process chamber chemistry and flow rates, substrate characteristics, other chamber characteristics (e.g., temperature), etc.

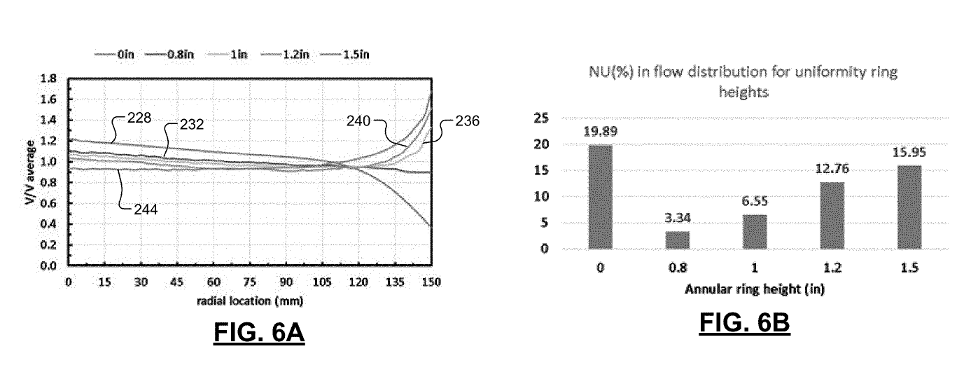

FIG. 6A illustrates different flow distributions (e.g., represented as local velocity normalized by average velocity) of an example recipe (e.g., N₂O+O₂+CF₄) in the substrate processing chamber 200 including the ring 224. The flow distributions correspond to a ring having the same diameter and distance D but with a height h adjusted from 0.0 inches (i.e., equivalent to no ring) to 1.5 inches. The flow distributions 228, 232, 236, 240, and 244 correspond to ring heights of 0.0 inches, 0.8 inches, 1.0 inches, 1.2 inches, and 1.5 inches, respectively. FIG. 6B illustrates non-uniformity percentages (NU(%)) in flow distribution for various heights of the annular ring 224. Accordingly, as shown, a ring height of 0.8 inches corresponds to the most uniform flow distribution and the lowest NU(%) for this example recipe.

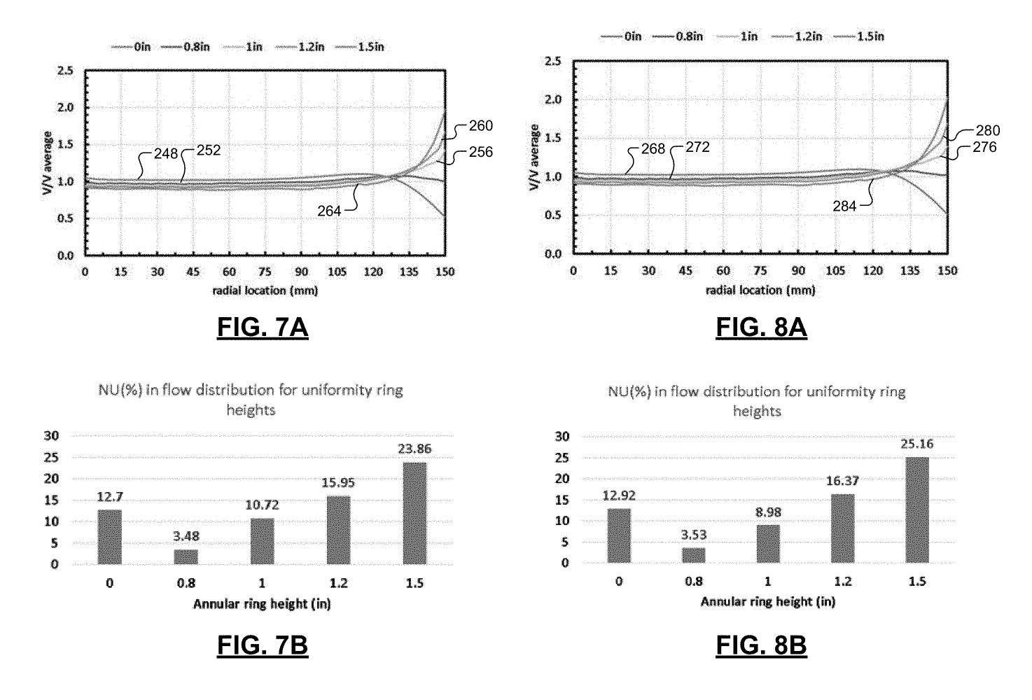

FIG. 7A illustrates different flow distributions (e.g., represented as local velocity normalized by average velocity) of another example recipe (e.g., CF₄) in the substrate processing chamber 200 including the ring 224. The flow distributions correspond to a ring having the same diameter and distance D but with a height h adjusted from 0.0 inches (i.e., equivalent to no ring) to 1.5 inches. The flow distributions 248, 252, 256, 260, and 264 correspond to ring heights of 0.0 inches, 0.8 inches, 1.0 inches, 1.2 inches, and 1.5 inches, respectively. FIG. 7B illustrates non-uniformity percentages (NU(%)) in flow distribution for various heights of the annular ring 224. Accordingly, as shown, a ring height of 0.8 inches corresponds to the most uniform flow distribution and the lowest NU(%) for this example recipe.

FIG. 8A illustrates different flow distributions (e.g., represented as local velocity normalized by average velocity) of another example recipe (e.g., H₂+NF₃) in the substrate processing chamber 200 including the ring 224. The flow distributions correspond to a ring having the same diameter and distance D but with a height h adjusted from 0.0 inches (i.e., equivalent to no ring) to 1.5 inches. The flow distributions 268, 272, 276, 280, and 284 correspond to ring heights of 0.0 inches, 0.8 inches, 1.0 inches, 1.2 inches, and 1.5 inches, respectively. FIG. 8B illustrates non-uniformity percentages (NU(%)) in flow distribution for various heights of the annular ring 224. Accordingly, as shown, a ring height of 0.8 inches corresponds to the most uniform flow distribution and the lowest NU(%) for this example recipe.

Accordingly, as shown above in FIGS. 6, 7, and 8, flow distribution over a surface of the substrate 212 can be controlled by incorporating the annular ring 224 and adjusting a height of the ring 224. Additional tuning of the flow distribution can be performed by adjusting the height of the substrate support (e.g., in examples where the substrate support, such as an ESC, is configured to be raised and lowered). In some examples, the ring 224 has a height of approximately 0.8 inches, or 20 mm (e.g., between 0.7 and 0.9 inches, or between 18 and 23 mm).

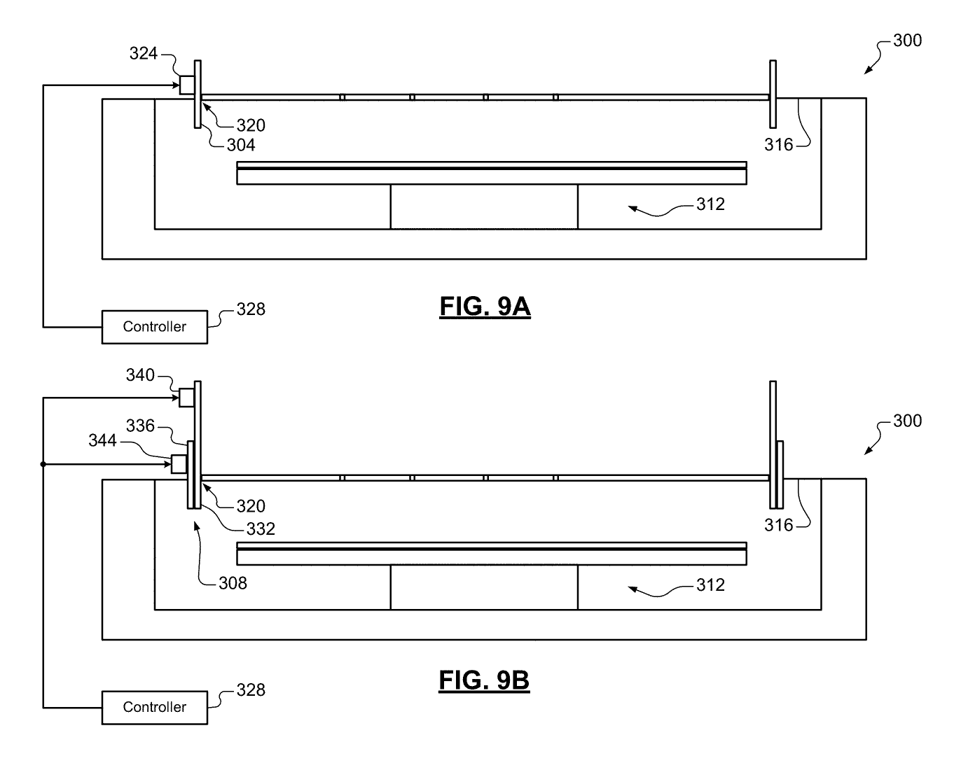

FIGS. 9A and 9B show portions of an example substrate processing chamber 300 including adjustable annular rings 304 and 308, respectively. The rings 304 and 308 may be configured to be raised and lowered in a vertical direction relative to a substrate support 312. For example, an upper surface 316 of the chamber 300 may include an opening (e.g., an annular slot) 320 arranged to receive the rings 304 and 308.

As shown in FIG. 9A, an actuator 324 is arranged to selectively raise and lower the ring 304 (e.g., in response to control signals received from controller 328). For example, the actuator 324 raises the ring 304 from the chamber 300 into the slot 320 to decrease the height of the ring 304. Conversely, the actuator 324 lowers the ring 304 through the slot 320 into the chamber 300 to increase the height of the ring 304.

As shown in FIG. 9B, the ring 308 includes a plurality of rings, such as, for example only, an inner ring 332 and an outer ring 336. Respective actuators 340 and 344 are arranged to selectively raise and lower the rings 332 and 336 (e.g., in response to control signals received from the controller 328). For example, the inner ring 332 may be lowered into the chamber 300 while the outer ring 336 is raised (e.g., such that a lower edge of the outer ring 336 is flush with the upper surface 316). In this arrangement, the ring 308 has a first diameter. Conversely, the inner ring 332 may be raised while the outer ring 336 is lowered into the chamber 300. In this arrangement, the ring 308 has a second diameter greater than the first diameter. Accordingly, a height and a diameter of the ring 308 can be selectively adjusted.

The controller 328 may selectively raise and lower the rings 304 and 308 according to a selected recipe, process step, input from a user, etc. For example, the controller 328 may store data (e.g., a lookup table) indexing various recipes, processes, steps, etc. by a desired ring height and/or diameter. Accordingly, when a particular recipe is selected, the controller 328 selectively raises and lowers the rings 304 and 308 according to the desired height and/or diameter for the selected recipe.

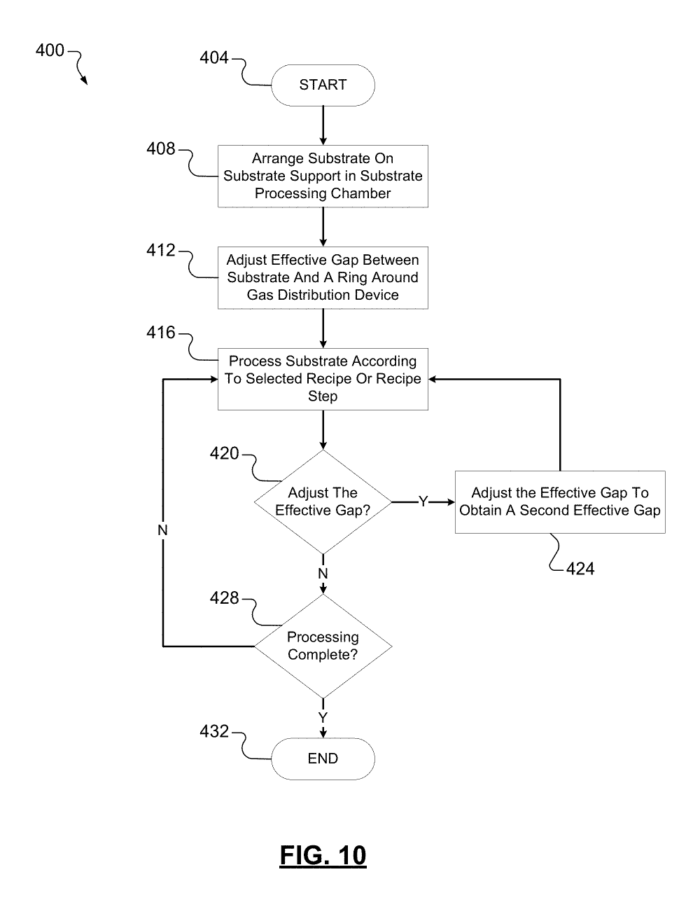

Referring now to FIG. 10, an example substrate processing method 400 according to the present disclosure begins at 404. At 408, a substrate is arranged on a substrate support in a substrate processing chamber. At 412, the method 400 adjusts an effective gap between the substrate and a ring (e.g., the ring 224, the ring 304, etc.) arranged around a gas distribution device in the chamber. For example, a controller (e.g., the controller 232) adjusts a height of the substrate support 236 to obtain a first effective gap according to a selected recipe or recipe step to be performed on the substrate. In other examples, the controller 328 adjusts a height of the ring 304 to obtain the first effective gap. At 416, the method 400 begins processing of the substrate according to the selected recipe or recipe step.

At 420, the method 400 determines whether to adjust the effective gap. For example, the controller 232 or 328 may determine whether to adjust the height of the substrate support 236 or the ring 304, respectively to obtain a second effective gap based on the recipe, changing conditions within the substrate processing chamber, user inputs, etc. If true, the method 400 continues to 424. If false, the method 400 continues to 428. At 424 the method 400 adjusts the effective gap to the second effective gap and continues to 416.

At 428, the method 400 determines whether processing of the substrate is complete. If true, the method 400 ends at 432. If false, the method 400 continues to 420.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system, comprising:
a gas distribution device arranged to distribute process gases over a surface of a substrate arranged in a substrate processing chamber having an upper chamber region and a lower chamber region;
a substrate support arranged in the lower chamber region of the substrate processing chamber below the gas distribution device; and
a ring arranged in the lower chamber region of the substrate processing chamber below the gas distribution device and above the substrate support, wherein the ring is arranged to surround (i) a faceplate of the gas distribution device and (ii) a region between the gas distribution device and the substrate support, and wherein a gap is defined between the substrate support and the ring.

2. The substrate processing system of claim 1, wherein the ring is configured to be selectively raised and lowered.

3. The substrate processing system of claim 2, wherein the ring includes an inner ring and an outer ring.

4. The substrate processing system of claim 3, wherein the inner ring and the outer ring are configured to be independently raised and lowered.

5. The substrate processing system of claim 2, further comprising a controller that selectively controls an actuator to raise and lower the ring.

6. The substrate processing system of claim 5, wherein the controller selectively raises and lowers the ring to adjust a height of the ring relative to the upper surface of the processing chamber.

7. The substrate processing system of claim 5, wherein the controller selectively raises and lowers the ring to adjust a distance between a lower edge of the ring and an upper surface of the substrate.

8. The substrate processing system of claim 5, wherein the controller selectively raises and lowers the ring based on a selected recipe being used in the substrate processing system.

9. The substrate processing system of claim 1, wherein the substrate support is configured to be raised and lowered.

10. The substrate processing system of claim 9, further comprising a controller that selectively controls an actuator to raise and lower substrate support.

11. The substrate processing system of claim 10, wherein the controller selectively raises and lowers the substrate support to adjust the gap defined between the substrate support and the ring.

12. The substrate processing system of claim 10, wherein the controller selectively raises and lowers the substrate support based on a selected recipe being used in the substrate processing system.

13. The substrate processing system of claim 1, wherein a diameter of the ring is greater than a diameter of the faceplate.

14. The substrate processing system of claim 1, further comprising a gap between a lower edge of the ring and an upper surface of the substrate support.

15. The substrate processing system of claim 1, wherein a height of the ring is approximately 0.8 inches.
